(19) United States
(12) Patent Application Publication
(10) Pub. No.: US 2012/0060890 A1
(43) Pub. Date: Mar. 15, 2012

(54) SOLAR CELL MODULE AND METHOD FOR MANUFACTURING THE SAME

(75) Inventors: Joong-Hyun PARK, Suwon-si (KR); Myung-Hun SHIN, Seoul (KR)

(73) Assignee: SAMSUNG ELECTRONICS CO., LTD., Suwon-si (KR)

(21) Appl. No.: 12/987,421

(22) Filed: Jan. 10, 2011

(30) Foreign Application Priority Data
Sep. 15, 2010 (KR) 10-2010-0090591

(51) Int. Cl. H01L 31/05; H01L 31/0224

(52) U.S. Cl. 136/244; 438/98; 257/E31.124

(57) ABSTRACT

Provided are a solar cell module and a manufacturing method thereof. The solar cell module includes a substrate having a first region and a second region; a first electrode disposed on the substrate, in the first region and the second region; and an upper cell disposed in the first region; and a lower cell disposed in the second region. The upper cell and the lower cell each include a first semiconductor layer, an intermediate layer, a second semiconductor layer, and a second electrode that are sequentially stacked. The threshold voltage in the lower cell is lower than the threshold voltage in the upper cell.

### CROSS-REFERENCE TO RELATED APPLICATION

This application claims priority to and the benefit of Korean Patent Application No. 10-2010-0090591, filed in the Korean Intellectual Property Office on Sep. 15, 2010, the entire content of which is incorporated herein, by reference.

### BACKGROUND

1. Field

The present invention relates to a solar cell module and a method for manufacturing the same.

2. Description of the Related Art

Solar cells convert solar energy into electrical energy. Generally, solar cells are diodes having a PN junction and may be classified into various types, in accordance with the material used as a light absorbing layer. Solar cells using silicon as the light absorbing layer may be classified as a crystalline substrate (wafer) type solar cell or a thin film type (amorphous, polycrystalline) solar cell.

Further, typical solar cells may also be classified as a compound thin film solar cell using CIGS (CuInGaSe2) or CdTe, a III-V-group solar cell, a dye-sensitized solar cell, or an organic solar cell. Since a thin film solar cell has a uniform open circuit voltage (Voc), regardless of size, patterning is performed so that unit cells are connected in series, to generate a desired voltage, when the solar cell module is manufactured. In this case, when defects occur in one cell, or when one cell is shaded, the defective/shaded cell limits the current of the entire module, thereby considerably reducing power generation.

The above information disclosed in this Background section is only for enhancement of understanding of the background of the invention and therefore it may contain information that does not form the prior art that is already known in this country to a person of ordinary skill in the art.

### SUMMARY

An exemplary embodiment of the present invention provide a solar cell module with a built-in bypass diode, and a manufacturing method thereof.

Additional features of the invention will be set forth in the description which follows, and in part will be apparent from the description, or may be learned by practice of the invention.

An exemplary embodiment of the present invention discloses a solar cell module, including: a substrate and including a first region and a second region; a first electrode disposed on the substrate, in the first and second regions; an upper cell disposed in the first region; and a lower cell disposed in the second region. The upper cell and the lower cell each include a first semiconductor layer, an intermediate layer, a second semiconductor layer, and a second electrode, which are sequentially stacked. The threshold voltage in the lower cell is lower than the threshold voltage in the upper cell.

Another exemplary embodiment of the present invention discloses a manufacturing method of a solar cell module, including: forming a first electrode on a first region and a second region of a substrate; patterning the first electrode to form a first groove G1; forming a first semiconductor layer on the first electrode; forming a second groove G2′ through the first semiconductor layer, in the second region; forming an intermediate layer on the first semiconductor layer; forming a second groove G2 through the intermediate layer and the first semiconductor layer, in the first region; forming a second semiconductor layer on the intermediate layer; and forming a second electrode on the second semiconductor layer. The second semiconductor layer contacts the first electrode within the second groove G2′.

Yet another exemplary embodiment of the present invention discloses a solar cell, including a substrate and a bypass diode unit disposed at an edge of the substrate, wherein the bypass diode unit includes: a first electrode having a first groove, disposed on the substrate; a first semiconductor layer disposed on the first electrode, having a second groove; an intermediate layer disposed on the first semiconductor layer; and a second semiconductor layer disposed on the intermediate layer, including a third groove. The intermediate layer contacts the first electrode within the second groove.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a schematic layout view showing a solar cell module, according to an exemplary embodiment of the present invention;

FIG. 2 is a cross-sectional view taken along line II-II′ of FIG. 1;

FIG. 3 is a cross-sectional view taken along line III-III′ of FIG. 1;

FIG. 4 is an equivalent circuit of a solar cell shown in FIG. 1, FIG. 2, and FIG. 3;

FIG. 5 is a schematic diagram showing the path of carrier movement in the solar cell module, according to an exemplary embodiment of the present invention;

FIG. 6 is a schematic layout view showing an operation of a manufacturing method of the solar cell, according to an exemplary embodiment of the present invention;

FIG. 7 is a cross-sectional view taken along line VII-VII′ of FIG. 6;

FIG. 8 is a schematic layout view showing aspects of the manufacturing method, according to an exemplary embodiment of the present invention;

FIG. 9 is a cross-sectional view taken along line IX-IX′ of FIG. 8;

FIGS. 10 and 11 illustrate aspects of the method with respect to the view of FIG. 9;

FIG. 12 is a schematic layout view showing aspects of the manufacturing method, according to an exemplary embodiment of the present invention;

FIG. 13 is a cross-sectional view taken along line XIII-XIII′ of FIG. 12;

FIGS. 14 and 15 are cross-sectional views respectively taken along lines XIV-XIV′ and XV-XV′ of FIG. 12;

FIG. 16 is a schematic layout view showing aspects of the manufacturing method, according to an exemplary embodiment of the present invention;

FIGS. 17 and 18 are cross-sectional views respectively taken along lines XVII-XVII′ and XVIII-XVIII′ of FIG. 16

FIG. 19 is a schematic layout view showing aspects of the manufacturing method, according to an exemplary embodiment of the present invention; and

FIG. 20 is a schematic perspective view showing a solar cell module, according to another exemplary embodiment of the present invention.

### DETAILED DESCRIPTION OF THE EMBODIMENTS

Exemplary embodiments of the invention are described more fully hereinafter with reference to the accompanying drawings. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

It will be understood that when an element or layer is referred to as being “on” or “connected to” another element or layer, it can be directly on or directly connected to the other element or layer, or intervening elements or layers may be present. In contrast, when an element is referred to as being “directly on” or “directly connected to” another element or layer, there are no intervening elements or layers present.

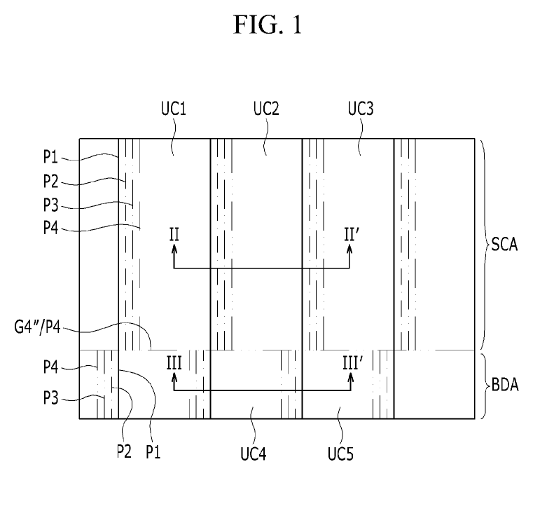

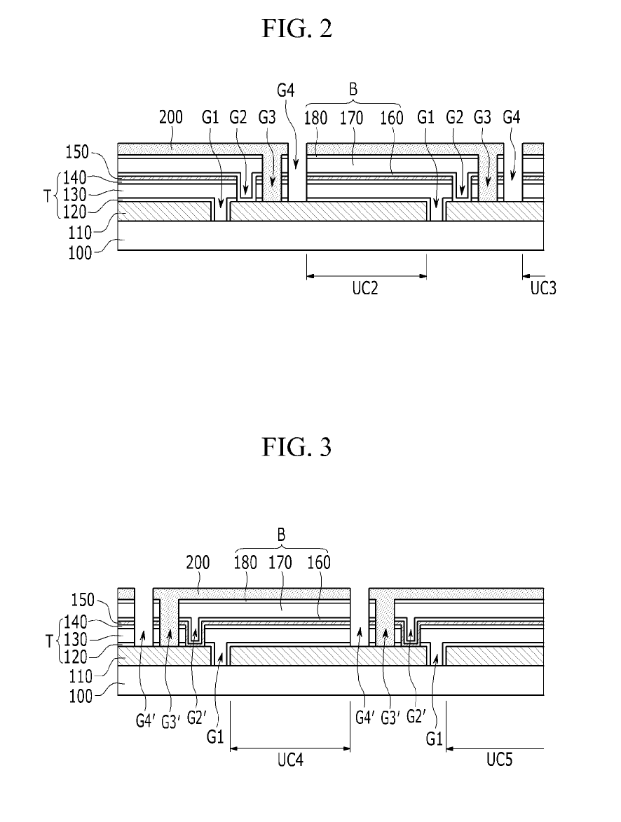

FIG. 1 is a schematic layout view showing a solar cell module, according to an exemplary embodiment of the present invention. FIG. 2 is a cross-sectional view taken along line II-II′ of FIG. 1. FIG. 3 is a cross-sectional view taken along line III-III′ of FIG. 1. Referring to FIGS. 1 to 3, the solar cell module includes a substrate 100 having a first region SCA and a second region BDA, and a first electrode 110 disposed on the substrate 100, in the first region SCA and the second region BDA. The substrate 100 may be a glass substrate. The first electrode 110 serves as a lower electrode and may be made of, SnO2, ZnO:Al, ZnO:B, ITO (Indium Tin Oxide), IZO (Indium Zinc Oxide), etc.

The solar cell module includes an upper cell disposed in the first region SCA and a lower cell disposed in the second region BDA. The upper cell and the lower cell each include a first semiconductor layer T, an intermediate layer 150, a second semiconductor layer B, and a second electrode 200. In this configuration, the first region SCA may correspond to a solar cell unit, and the second region BDA may correspond to a bypass diode unit.

A first groove pattern P1 is formed on the solar cell module. The first groove pattern P1 includes first grooves G1 formed in the first electrode 110. The first grooves G1 extend across the first region SCA and the second region BDA, in a generally parallel orientation. The first grooves G1 are filled with at least a portion of the first semiconductor layer T.

A second groove pattern P2 is formed next to the first groove pattern P1, in the first region SCA and the second region BDA. The second groove pattern P2 includes second grooves G2 and G2′. The second grooves G2 are formed in the first semiconductor layer T and the intermediate layer 150, and extend across the first region SCA. The second grooves G2 prevent portions of the intermediate layer 150 and the second electrode 200 from being short circuited.

The second grooves G2′ are formed in the first semiconductor layer T and extend across the second region BDA. The second grooves G2′ are not formed in the intermediate layer 150. Instead, the intermediate layer 150 contacts the sidewalls and bottom of each of the second grooves G2′. In other words, the intermediate layer 150 contacts edges of the first semiconductor layer T and an upper surface of the first electrode 110. The semiconductor layer B is disposed on the intermediate layer 150 and fills the second grooves G2′.

A third groove pattern P3 is formed next to the second groove pattern P2. The third groove pattern P3 includes third grooves G3 and G3′ that are formed in the first semiconductor layer T, intermediate layer 150, and second semiconductor layer B. The third grooves G3 extend across the first region SCA, and the third grooves G3′ extend across the second region BDA.

A fourth groove pattern P4 is formed next to the third groove pattern P3, in the first region SCA and the second region BDA. The fourth groove pattern P4 also extends between the first region SCA and the second region BDA. The fourth groove pattern includes fourth grooves G4, G4′, and G4″ that are formed in the first semiconductor layer T, the intermediate layer 150, the second semiconductor layer B, and the second electrode 200. The fourth grooves G4 extend across the first region SCA, and the fourth grooves G4′ extend across the second region BDA. The fourth groove G4″ extends between the first region SCA and the second region BDA. The fourth grooves G4 serve to separate unit cells UC1, UC2, and UC3 from each other. The fourth grooves G4′ separate unit cells UC4 and UC5. The fourth groove G4″ separates the first region SCA and the second region BDA and thereby, separates unit cells UC2 and UC3 from unit cells UC4 and UC5.

The groove patterns P1-P4 may be arranged in the same order in each of the unit cells UC1, UC2, and UC3 of the first region SCA. The groove patterns P1-P4 may also be arranged in the same order in each of the unit cells UC4 and UC5 of the second region BDA. However, the order of the groove patterns P1-P4 of the first region SCA may be opposite to the order of the groove patterns in the second region BDA.

The first semiconductor layer T, the intermediate layer 150, and the second semiconductor layer B will now be described in detail. The first semiconductor layer T is formed by sequentially stacking a first P layer 120 having a p-type impurity, a first I layer 130 made of an intrinsic semiconductor, and a first N layer 140 having an N-type impurity. The first I layer 130 serves as a light absorbing layer and forms a path along which an electric field is formed to move carriers from the first P layer 120 to the first N layer 140. In other words, carriers are generated in the first I layer 130, by sunlight, electrons are collected in the first N layer 140 and holes are collected in the first P layer 120, by the drift of an inner electric field, thereby generating current.

The first P layer 120 may be made of boron-doped amorphous silicon (a-Si:H), amorphous silicon carbide (a-SiC:H), or micro crystalline silicon (mc-Si:H), for example. The first 1 layer 130 and the first N layer 140 may be made of amorphous silicon (a-Si:H), for example.

The second semiconductor layer B is formed by sequentially stacking a second P layer 160, a second I layer 170, and a second N layer 180, on the intermediate layer 150. The intermediate layer 150 serves to increase light utilization efficiency in a tandem-type solar cell structure, according to the exemplary embodiment of the present invention. To this end, the intermediate layer 150 electrically connects the first semiconductor layer T to the second semiconductor layer B.

The intermediate layer 150 may reflect a portion of light that passes through the first semiconductor layer T without being absorbed, back to the first semiconductor layer T. The intermediate layer 150 may made of a conductive material having a lower reflectance than silicon.

For example, the intermediate layer 150 may made of a conductive inorganic oxide and/or a conductive transparent metal oxide. The conductive inorganic oxide and/or the conductive transparent metal oxide may include ZnO, IGZO, ITO, SiC doped with the N-type impurity, SiOx doped with the N-type impurity, SiNx doped with the N-type impurity, or the like.

The second I layer 170 may be made of micro crystalline silicon (mc-Si:H). The second electrode 200 may be made of a reflective metal material. The second region BDA may be disposed at the edge of the solar cell module. A frame (not shown) may be formed at the edges of the solar cell module, to fix the solar cell and block external moisture. The frame may be made of a reflective metal material. The second region BDA may be covered by the frame.

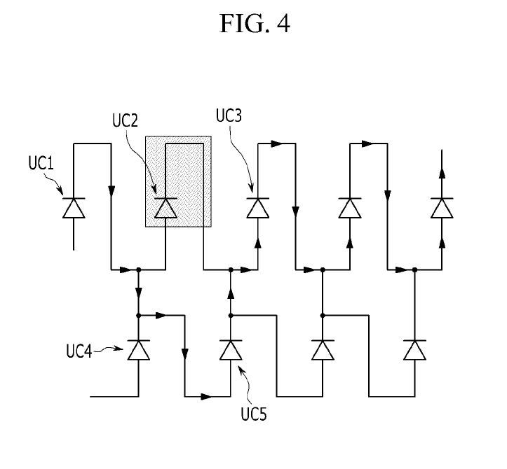

FIG. 4 is an equivalent circuit of the solar cell shown in FIGS. 1 to 3, and FIG. 5 is a schematic diagram showing the path of carrier movement in the solar cell module, according to an exemplary embodiment of the present invention. Referring to FIG. 4, PIN polarities of the unit cells UC1, UC2, and UC3 in the first region SCA and the unit cells UC4 and UC5 in the second region BDA, are opposite to each other. The unit cells UC1, UC2, and UC3 are connected in series, and the UC4 and UC5 are connected in series, in a reverse direction to that of the unit cells of the first region SCA.

When the solar is generally operated, each unit cell UC1, UC2, and UC3 receives solar energy to form a forward bias, such that current flows. In this case, the second region BDA is shaded, to increase the resistance to current flow. On the other hand, when one unit cell UC2 of the first region SCA is defective or shaded, a reverse bias is formed in the defective unit cell UC2, and current may flow through the unit cell UC5, where the relative forward bias is formed.

As described above, the solar cell module has different patterns formed in the intermediate layer 150, in the first region SCA (the solar cell region) and the second region BDA (bypass diode region).

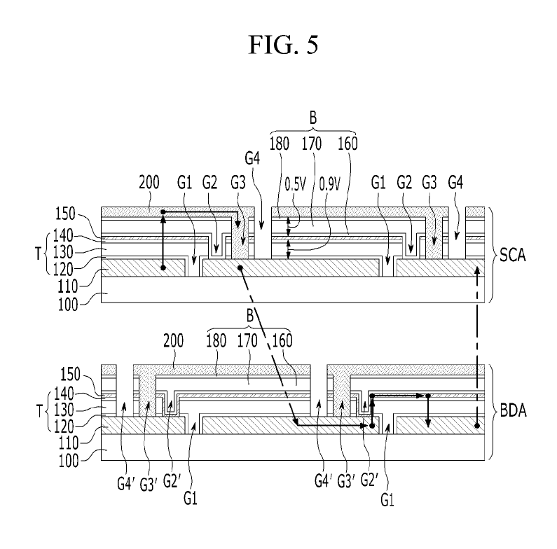

Referring to FIG. 5, even when the unit cell UC2 is shaded or is defective, current can be transferred through the second region BDA, which is a bypass diode region. Since the first region SCA and the second region BDA share the same first electrode 110, when the unit cell UC2 of the solar cell region is a dead cell, current is transferred from the first region SCA to the second region BDA, through the first electrode 110.

The intermediate layer 150 is connected to the first electrode 110, within the second groove G2′, and current flows into the first semiconductor layer T, such that the threshold voltage becomes 0.9V. In other words, the unit cell UC5 of the second region BDA generates electricity in the first semiconductor layer T and does not generate electricity in the second semiconductor layer B.

As compared to the 1.4V threshold voltage of the unit cells UC1, UC2, and UC3 disposed in the first region SCA, the threshold voltage of the unit cells UC4 and UC5 disposed in the second region BDA is reduced to 0.9V. Therefore, since the threshold voltage of the second region BDA is relatively small, current can flow even at a low voltage, thereby making it possible to maximize an increase in peak power.

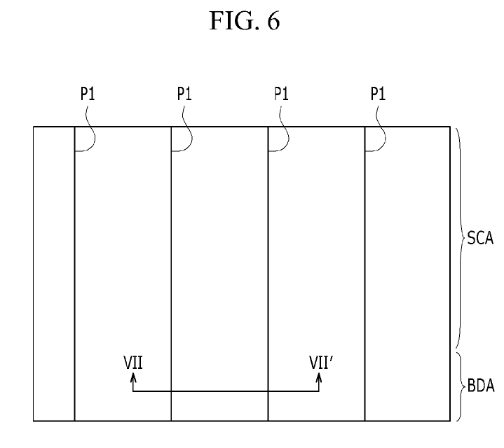

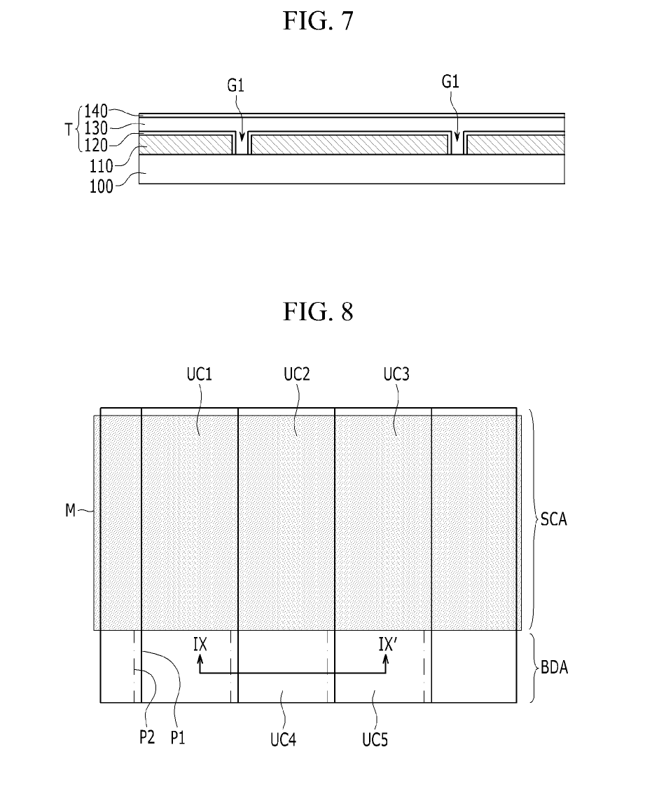

FIG. 6 is a schematic layout view showing the manufacturing method of the solar cell, and FIG. 7 is a cross-sectional view taken along line VII-VII′ of FIG. 6. Referring to FIGS. 6 and 7, the first electrodes 110 are formed on the substrate 100, in the first region SCA and the second region BDA.

The first electrodes 110 are patterned along the first groove pattern P1, to form the first grooves G1. The first semiconductor layer T is formed on the first electrodes 110, in the first region SCA and the second region BDA. The first semiconductor layer T may be formed by sequentially stacking the first P layer 120, the first I layer 130, the first N layer 140.

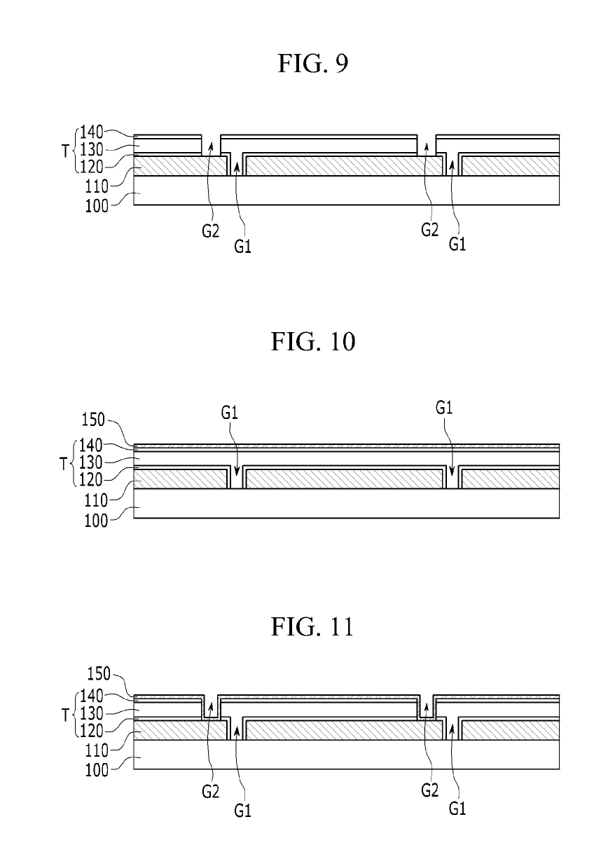

FIG. 8 is a schematic layout view showing the manufacturing method, and FIG. 9 is a cross-sectional view taken along line IX-IX′ of FIG. 8. Referring to FIGS. 8 and 9, the second grooves G2′ are formed in the second region BDA, along the second grove pattern P2. The second grooves G2′ may be formed in the first semiconductor layer T. A laser may be used to form the second grooves G2′. When forming the second grooves G2′ with the laser, the first region SCA may be covered by a mask M.

Referring to FIGS. 10 and 11, the intermediate layer 150 is formed on the first semiconductor layer T, in the first region SCA and the second region BDA. As shown in FIG. 10, in the first region SCA, the intermediate layer 150 is formed on the upper surface of the first semiconductor layer T. As shown in FIG. 11, in the second region BDA, the intermediate layer 150 is formed on the upper surface of the first semiconductor layer T, as well as inside of the second grooves G2′.

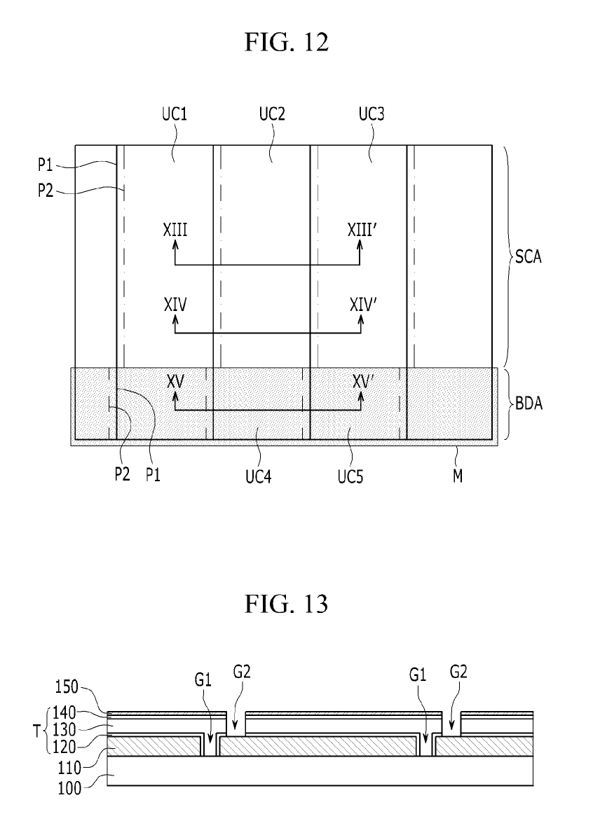

FIG. 12 is a schematic layout view showing the manufacturing method, and FIG. 13 is a cross-sectional view taken along line XIII-XIII′ of FIG. 12. Referring to FIGS. 12 and 13, the first semiconductor layer T and the second grooves G2 are formed in the intermediate layer 150, in the first region SCA.

The second grooves G2 may be formed along the second groove pattern P2. The arrangement order of the first groove pattern P1 and the second groove pattern P2 in the first region SCA may be opposite to the arrangement order of the first groove pattern P1 and the second groove pattern P2 in the second region BDA. When forming the second grooves G2 in the first region SCA, the second region BDA may be covered by a mask M.

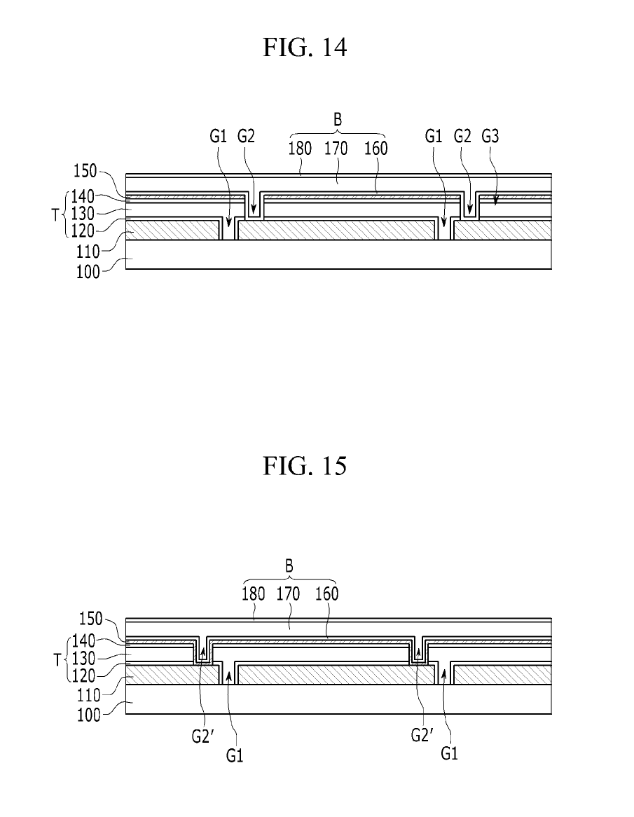

FIGS. 14 and 15 are cross-sectional views respectively taken along lines XIV-XIV′ and XV-XV′ of FIG. 12. Referring to FIGS. 14 and 15, the second semiconductor layer B is formed on the intermediate layer 150, in the first region SCA and the second region BDA.

The second semiconductor layer B may be formed by sequentially stacking the second P layer 160, the second I layer 170, and the second N layer 180. In the first region SCA, the second semiconductor layer B may fill the second grooves G2, and in the second region BDA, the intermediate layer 150 and the second semiconductor layer B may fill the second grooves G2′.

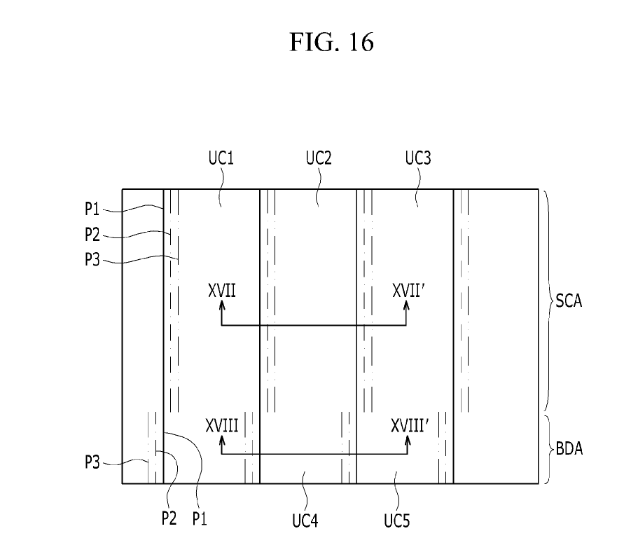

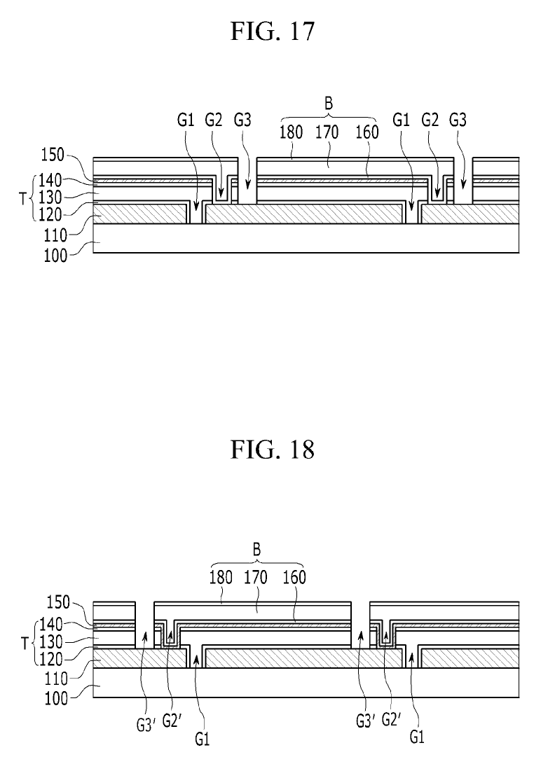

FIG. 16 is a schematic layout view showing the manufacturing method of the solar cell module, according to aspects of the present invention, and FIGS. 17 and 18 are cross-sectional views respectively taken along lines XVII-XVII′ and XVIII-XVIII′ of FIG. 16. Referring to FIGS. 16 to 18, the second semiconductor layer B, which is disposed in the first region SCA and the second region BDA, is patterned, thereby forming the third grooves G3 and G3′, in the first semiconductor layer T, the intermediate layer 150, and the second semiconductor layer B.

In the first region SCA and the second region BDA, the third grooves G3 and G3′ may each be formed along the third groove pattern P3. The arrangement order of the first groove pattern P1, the second groove pattern P2, and the third groove pattern P3 in the first region SCA may be opposite to the arrangement order of the groove patterns P1, P2, and P3 in the second region BDA. When forming the third grooves G3 in the first region SCA, the second region BDA may be covered by a mask (not shown). When forming the third groove G3′ in the second region BDA, the first region SCA may be covered by a mask (not shown).

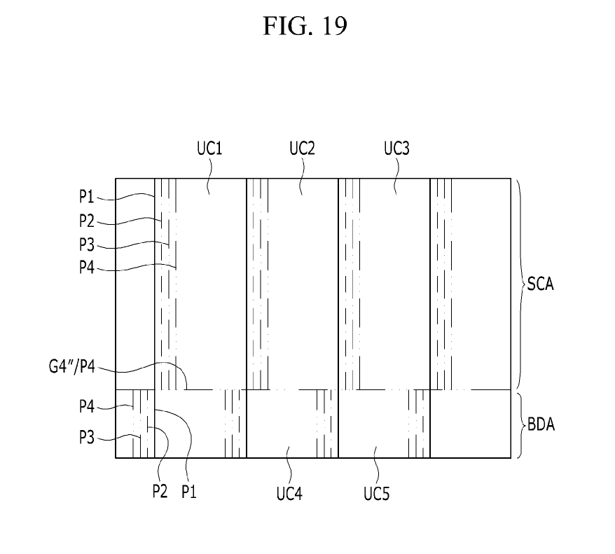

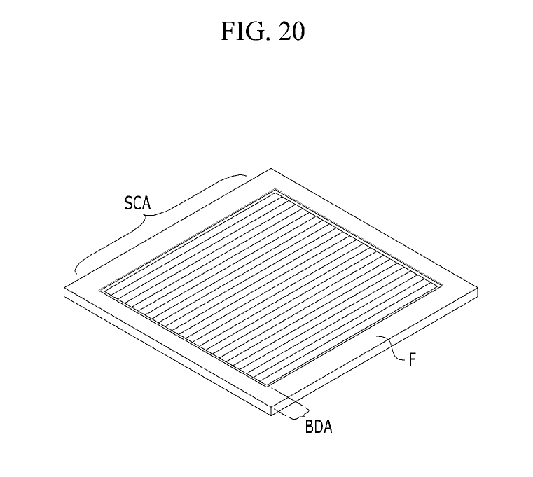

FIG. 19 is a schematic layout view showing the manufacturing method of the solar cell module, according to aspects the present invention. Referring back to FIGS. 19, FIG. 2, and FIG. 3, the second electrodes 200 are formed on the second semiconductor layer B, in the first region SCA and the second region BDA.

The second electrode 200 may be formed to fill the third grooves G3 and G3′. The second electrodes 200 in the first region SCA and the second region BDA are patterned to form the fourth grooves G4, G4′, and G4″ in the first semiconductor layer T, the intermediate layer 150, the second semiconductor layer B, and the second electrode 200.

In the first region SCA and the second region BDA, the fourth grooves G4, G4′, and G4″ may be formed along corresponding portions of the fourth groove pattern P4. The arrangement order of the first pattern region P1, the second pattern region P2, the third pattern region P3, and the fourth pattern region P4 in the first region SCA may be opposite to the arrangement order thereof in the second region BDA.

When forming the fourth grooves G4 in the first region SCA, the second region BDA may be covered by a mask (not shown). When forming the fourth grooves G4′ in the second region BDA, the first region SCA may be covered by a mask (not shown). The fourth groove G4″ is formed in the interface between the first region SCA and the second region BDA (in the horizontal direction). The fourth groove G4″ may be formed first, followed by the formation of the fourth grooves G4 and G4′, according to some aspects.

FIG. 20 is a schematic perspective view showing a solar cell module, according to another exemplary embodiment of the present invention. Referring to FIG. 20, a frame F may be formed at the edges of the solar cell module. The frame F may serve to fix the solar cell module and/or block the external moisture. In the solar cell module, the second region BDA, corresponding to the bypass diode unit is covered by the frame F.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A solar cell module, comprising:
a substrate having a first region and a second region;
a first electrode disposed on the substrate and in the first region and the second region;
an upper cell disposed in the first region and connected to the first electrode; and
a lower cell disposed in the second region and connected to the first electrode; wherein,
the upper cell and the lower cell each comprise a first semiconductor layer, an intermediate layer, a second semiconductor layer, and a second electrode that are sequentially stacked, and
the threshold voltage of the lower cell is lower than the threshold voltage of the upper cell.

2. The solar cell module of claim 1, wherein a first groove (G1) is formed through the first electrode and is formed in the first region and the second region.

3. The solar cell module of claim 2, wherein:
a second groove (G2) is formed through the first semiconductor layer and the intermediate layer and is formed in the upper cell;
a second groove (G2′) is formed through the first semiconductor layer and is formed in the lower cell;
the second semiconductor layer contacts the first electrode within the second groove (G2); and
the intermediate layer contacts the first electrode within the second groove (G2′).

4. The solar cell module of claim 3, wherein:
a third groove (G3) is formed in the upper cell and is formed through the first semiconductor layer, the intermediate layer, and the second semiconductor layer;
a third groove (G3′) is formed in the lower cell and is formed through the first semiconductor layer, the intermediate layer, and the second semiconductor layer;
a fourth groove (G4) is formed in the upper cell and is formed through the first semiconductor layer, the intermediate layer, the second semiconductor layer, and the second electrode;
a fourth groove (G4′) is formed in the lower cell and is formed through the first semiconductor layer, the intermediate layer, the second semiconductor layer, and the second electrode;
in the upper cell, the grooves are arranged in a first direction, in the following order: the second groove (G2), the third groove (G3), the fourth groove (G4), and the first groove (G1); and
in the lower cell the grooves are arranged in the first direction, in the following order: the first groove (G1), the fourth groove (G4′), the third groove (G3′), and the second groove (G2′).

5. The solar cell module of claim 4, wherein a fourth groove (G4″) is formed in between the first region and the second region, the fourth groove (G4″) separating the upper cell and the lower cell.

6. The solar cell module of claim 5, wherein the fourth groove (G4″) extends in a direction that is substantially perpendicular to the direction in which the fourth grooves (G4) and (G4′) extend.

7. The solar cell module of claim 1, further comprising: a frame disposed on the edges of the substrate and covering the second region.

8. The solar cell module of claim 1, wherein the upper cell is a solar cell and the lower cell is a bypass diode.

9. The solar cell module of claim 1, wherein the intermediate layer comprises at least one of zinc oxide (ZnO), tin oxide (SnO), and silicon oxide (SiOx).

10. The solar cell module of claim 1, wherein the upper cell and the lower cell are connected by the first electrode.

11. A manufacturing method of a solar cell module, comprising:
forming a first electrode on a substrate and in a first region and a second region of the substrate;
forming a first groove (G1) through the first electrode and in the first and second regions;
forming a first semiconductor layer on the first electrode;
forming a second groove (G2′) through the first semiconductor layer and in the second region;
forming an intermediate layer on the first semiconductor layer;
forming a second groove (G2) through the intermediate layer and the first semiconductor layer and in the first region;
forming a second semiconductor layer on the intermediate layer; and
forming a second electrode on the second semiconductor layer,
wherein the second semiconductor layer contacts the first electrode within the second groove (G2′).

12. The method of claim 11, further comprising:
forming a third groove (G3) through the first semiconductor layer, the intermediate layer, and the second semiconductor layer, in the first region;
forming a third groove (G3′) in the first region and through the first semiconductor layer, the intermediate layer, and the second semiconductor layer;
forming a fourth groove (G4) in the first region and through the first semiconductor layer, the intermediate layer, the second semiconductor layer, and the second electrode;
forming a fourth groove (G4′) in the second region and through the first semiconductor layer, the intermediate layer, the second semiconductor layer, and the second electrode, wherein,
in the upper region, the grooves are arranged in a first direction, in the following order: the second groove (G2), the third groove (G3), the fourth groove (G4), and the first groove (G1), and
in the lower region, the grooves are arranged in the first direction, in the following order: the first groove (G1), the fourth groove (G4′) the third groove (G3′), and the second groove (G2′).

13. The method of claim 12, further comprising forming a fourth groove (G4″) between the first region and the second region.

14. The method of claim 13, wherein the fourth groove (G4″) extends in a direction that is generally perpendicular to the direction in which the fourth grooves (G4) and (G4′) extend.

15. The method of claim 11, wherein the forming the second groove (G2′) comprises radiating laser on the second region, while the first region is covered by a first mask.

16. The method of claim 15, wherein the forming the second groove (G2) comprises radiating laser on the first region, while the second region is covered by a second mask.

17. The method of claim 11, further comprising disposing a frame on the edges of the substrate, such that the frame covers the second region.

18. A solar cell, comprising:
a substrate; and
a bypass diode unit disposed at an edge of the substrate, the bypass diode unit comprising:
a first electrode disposed on the substrate and having a first groove formed there through;
a first semiconductor layer disposed on the first electrode and having a second groove formed there through;
an intermediate layer disposed on the first semiconductor layer; and
a second semiconductor layer disposed on the intermediate layer and having a third groove formed there through,
wherein the intermediate layer contacts the first electrode within the second groove.

19. The solar cell of claim 18, wherein the bypass diode further comprises a second electrode disposed on the second semiconductor layer and having a fourth groove formed there through.

20. The solar cell of claim 19, further comprising a frame disposed on the edges of the substrate and covering the bypass diode unit.
